(19) United States
(12) Patent Application Publication
(10) Pub. No.: US 2015/0129018 A1
(43) Pub. Date: May 14, 2015

(54) MULTILAYER ENCAPSULATED FILM FOR PHOTOVOLTAIC MODULES

(71) Applicant: NOVOPOLYMERS N.V., Puurs (BE)

(72) Inventors: Johan Willy Declerck, Grimbergen (BE); Koen Hasaers, Brecht (BE); Kristof Proost, Hemiksem (BE)

(21) Appl. No.: 14/400,738

(22) PCT Filed: May 15, 2013
(86) PCT No.: PCT/EP2013/060073

§ 371 Date: Nov. 12, 2014

(30) Foreign Application Priority Data
May 16, 2012 (NL) 2008837
May 16, 2012 (NL) 2008838
May 16, 2012 (NL) 2008839
May 16, 2012 (NL) 2008840
May 16, 2012 (NL) 2008841

(51) Int. Cl. H01L 31/048; H01L 31/18; H01L 31/049

(52) U.S. Cl. CPC H01L 31/0481; H01L 31/049; H01L 31/18
USPC 136/251; 438/64

(57) ABSTRACT

The present invention relates to a multilayer film for the encapsulation of photovoltaic cells, comprising: (a) at least a first, outer thermoplastic polymer layer;(b) a second thermoplastic polymer intermediate layer arranged between the first and the third layer, and (c) a second, outer thermoplastic polymer layer, wherein at least one of layers (a), (b) or (c) is opaque.

The present invention relates to a multilayer encapsulant film for photovoltaic modules, a process for the production of the encapsulant film, and its use in a process for the production of photovoltaic modules.

### BACKGROUND OF THE INVENTION

Photovoltaic cells can typically be categorized into two types based on the light absorbing material used, namely bulk or wafer-based photovoltaic cells and thin film photovoltaic cells. Typically the cells are combined in a certain pattern, and are interconnected to create a single power output.

The modules are typically enclosed in a matrix of polymeric materials. The photovoltaic cells typically comprise a doted semiconductor material, which converts incoming light into electric energy. Commonly used materials include monocrystalline silicon (c-Si), poly- or multi-crystalline silicon (poly-Si or mc-Si) to form the more traditional wafer-based photovoltaic cells. Alternatively, thin film photovoltaic cells are formed from materials that include amorphous silicon (a-Si), microcrystalline silicon ([mu]c-Si), cadmium telluride (CdTe), copper indium selenide (CuInSe2 or CIS), copper indium/gallium diselenide (CuInxGa(i-X)Se2 or CIGS), light absorbing dyes, and organic semiconductors.

Photovoltaic modules derived from wafer-based photovoltaic cells often comprise a series of self-supporting wafers that are soldered together. The wafers generally have a thickness of between 180 and 240 μm, commonly known as photovoltaic cell layer. The layer typically further comprises electrical wirings such as cross ribbons connecting the individual cell units and bus bars having one end connected to the cells and the other exiting the module.

The photovoltaic cell layer is usually wedged between layers of polymeric encapsulants and outer protective layers to form a weather resistant module. Subject to the outdoor application, the photovoltaic modules have to be durably resistant to the different weathering conditions, including variations in humidity and temperature, exposure to UV and other radiation, and exposure to chemicals and/or (micro)biological growth related with the outdoor exposure; migration of ions, and oxidation.

In general, a photovoltaic cell module comprises, starting from the light incident side to the back side, an incident layer or front sheet; a front encapsulant layer; the photovoltaic cell layer; a back encapsulant layer, and a backing layer or backsheet.

The role of the front sheet is to protect the photovoltaic module against mechanical impact and weathering while allowing light to pass to the active layer. Typical front sheets are made from a glass pane, usually low-iron tempered glass with a thickness of 4 mm or 3.2 mm, or from transparent polymers such as PMMA, or transparent multilayer composites. The front sheet is typically connected to the photovoltaic cell layer by means of a transparent encapsulant, typically a polymer layer that can act as a heat melt adhesive. The backside of the photovoltaic cell layer is typically attached to a second encapsulant layer, followed by the backsheet as the rear protective layer of the module.

Frontsheet and backsheet have to provide barrier properties versus humidity; mechanical strength; cut-through resistance; good adhesion to the photovoltaic cells and their connectors; weathering resistance and/or electrical insulation properties.

The current layup process for photovoltaic modules comprises layering the front sheet, the encapsulant film, the cells with ribbons and connectors, the back encapsulant and a backsheet, or an encapsulant integrated multilayer backsheet are placed with the front sheet upside down, and are then introduced into a vacuum laminator, and finally pressure bonded under conversion heating, whereby the photovoltaic cells and ribbons are firmly embedded in the two encapsulant films which melt and crosslink in case of a cross linked formulated polymer system.

This process thus typically involves the handling of at least three different films, i.e. front and back encapsulant film, followed by the backsheet film.

A problem with the encapsulant films is that films comprising EVA copolymers tend to be subject to shrinking due to annealing after a co-extrusions, leading to stress on the photovoltaic cell components and front and backsheet during the lamination process. Applications surprisingly found that the use of a different material layer with lower shrink properties may effectively reduce the shrinking and hence maintain the film dimensions during the heating up step in lamination process before pressure is applied on the stack. Furthermore, the presence of a different polymer in the encapsulant as a separate layer may advantageously allow to tailor film properties, such as enhanced barrier properties.

Applicants have now surprisingly found that the complexity of the process can be improved significantly by reducing the amount of waste materials as well as deletes an additional lay-up step, while also removing the need for solvent based adhesives, while at the same time improving barrier properties of the film.

### SUMMARY OF THE INVENTION

Accordingly, the present invention relates to a multilayer film for the encapsulation of photovoltaic cells, comprising: (a) at least a first outer thermoplastic polymer layer; (b) a second thermoplastic polymer intermediate layer arranged between the first and the third layer; and (c) a second outer thermoplastic polymer layer, wherein at least one of (a), (b) or (c) is opaque.

### SHORT DESCRIPTION OF THE FIGURES

The following figures serve to illustrate preferred embodiments of the subject invention:

FIG. 1 discloses a first preferred embodiment of the subject invention. Herein disclosed is a multilayer film (1) comprising a first, transparent encapsulant layer (11) adhering to a second, opaque or transparent encapsulant layer (12), the latter adhering to an opaque or transparent film (13). Either of 12 or 13 may be opaque, or one of them, while the other may then be transparent.

FIG. 2 discloses a second preferred embodiment of the subject invention. Herein disclosed is a multilayer film (1) comprising a first, transparent encapsulant layer (11) adhering to a second, opaque encapsulant layer (12), the later adhering to an adhesion promoting layer (13), the latter again adhering to film (14).

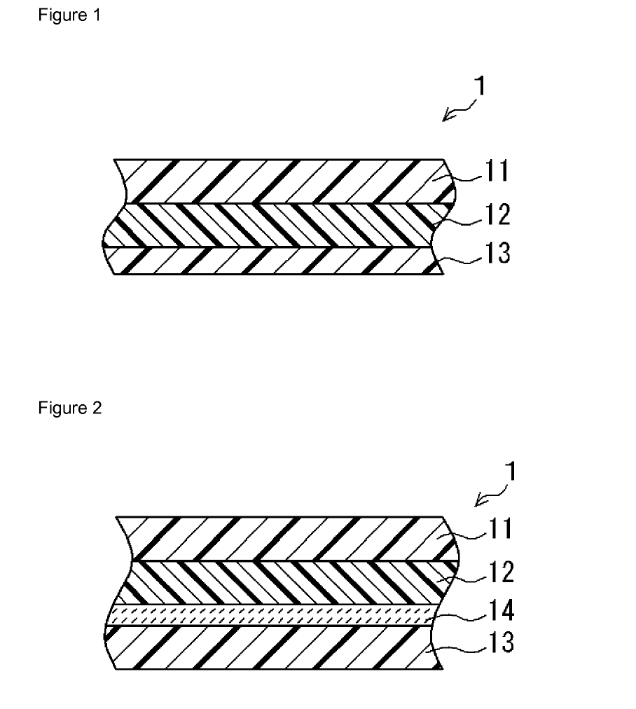

The first layer (a), when employed in the production of photovoltaic cells, is facing upward, the third layer (c), downward.

The term “upward facing” as used herein refers to the side of the film that will be layered into a photovoltaic module facing the light incident side.

The term “downward facing” as used herein accordingly refers to the side of the film that will be layered into a photovoltaic module facing the side that is facing the backside of the photovoltaic module. However, the film or sheet according to the invention does not require to prepared in a manner whereby an upward facing side is facing upward.

There are no specific restrictions on the thickness of individual layers used in the laminated film described herein. The overall film thickness preferably is in the range of from 150 to 1000 μm. The encapsulant layers (a) to (c) preferably have a combined thickness of from 150 to 600 μm.

The one or more outer polymer layers (a) preferably have a thickness of from 50 to 250 μm. The thickness of the layer will be advantageously be chosen sufficiently high to embed photovoltaic cell and any ribbons, where present during the lamination process.

For classical photovoltaic cells with ribbon connectors, the one or more outer layer preferably has a thickness of from 160 to 250 μm, more preferably of from 170 to 210 μm. The one or more inner layer (b) preferably has a thickness of from 10 to 250 μm. The thickness of the layer (b) depends on the polymer material employed, as well as on the function and type of photovoltaic cell.

The one or more outer layer (c) preferably have a thickness of from 50 to 250 μm. The thickness of the layer (c) is typically similar or equal to the thickness of layer (a). The thickness of the layers will be advantageously be chosen sufficiently high to embed photovoltaic cell and any ribbons, where present during the lamination process.

In a preferred embodiment, layer (a) and layer (c) comprise ethylene vinyl acetate copolymer, whereas layer (b) comprises a different polymer, either an ethylene vinyl acetate copolymer with a different composition, e.g.

with a lower vinyl acetate monomer content, or one or more polymers of a different composition, such as preferably a polyolefin, or a block copolymer.

In this embodiment, which is particularly useful for back contact cells, the thickness of layer (a) and (c) is in the range of from 50 to 150 μm, more preferably in the range of from 40 to 100 μm.

In a particularly preferred embodiment, layer (a) is transparent, and comprises ethylene vinyl acetate copolymer, with a thickness of from 35 to 250 μm; layer (b) is transparent or opaque, and does not comprise an ethylene vinyl acetate copolymer, and has a thickness of from 15 to 150 μm; and layer (c) is a transparent, or preferably opaque layer comprising an ethylene vinyl acetate copolymer, and has a thickness in the range of from 35 to 250 μm.

In a preferred embodiment, outside layers (a) and (c) comprise EVA copolymers, and inner layer (b) comprises a recycled EVA copolymer material. Preferably all three layers may be transparent.

At least one of layers (b) and (c) is a white pigmented layer acting as a diffuse reflector. In a preferred embodiment, layer (b) may be a polyolefin layer, either white pigmented, or transparent.

In yet a further preferred embodiment, layer (c) comprises recycled EVA material, and is a diffuse reflector.

Unless stated otherwise, all percentages, parts, ratios, etc., are by weight. When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

As used herein, the terms “comprises,” “comprising,” “includes,” “including,” “containing,” “characterized by,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

Further, unless expressly stated to the contrary, “or” refers to an inclusive or and not to an exclusive or. The transitional phrase “consisting essentially of limits the scope of a claim to the specified materials or steps and those that do not materially affect the basic and novel characteristic(s) of the claimed invention.

Where applicants have defined an invention or a portion thereof with an open-ended term such as “comprising,” it should be readily understood that unless otherwise stated the description should be interpreted to also describe such an invention using the term “consisting essentially of”.

Use of “a” or “an” are employed to describe elements and components of the invention. This is merely for convenience and to give a general sense of the invention. This description should be read to include one or at least one and the singular also includes the plural unless it is obvious that it is meant otherwise.

As used herein, the term “film” refers to a sheet or sheet-like substrate, such as those sheets or films typically employed in the photovoltaic cell production.

In describing certain polymers it should be understood that sometimes applicants are referring to the polymers by the monomers used to produce them or the amounts of the monomers used to produce the polymers. While such a description may not include the specific nomenclature used to describe the final polymer or may not contain product-by-process terminology, any such reference to monomers and amounts should be interpreted to mean that the polymer comprises those monomers, i.e. copolymerized units of those monomers, or that amount of the monomers, and the corresponding polymers and compositions thereof.

In describing and/or claiming this invention, the term “copolymer” is used to refer to polymers formed by copolymerization of two or more monomers. Such copolymers include dipolymers, terpolymers or higher order copolymers. The “melt flow index”, further referred to as MFI herein, is a measure of the ease of flow of the melt of a thermoplastic polymer. It is defined as the mass of polymer, in grams, flowing in ten minutes through a capillary of a specific diameter and length by a pressure applied via prescribed alternative gravimetric weights for alternative prescribed temperatures, and is determined according to ASTM D1238.

It should be noted that where a polymer is formulated with a crosslinking mechanism that is initiated above a certain temperature, e.g. EVA copolymers and peroxides, the rheology values employed herein refer to materials that are not, or only partially cross-linked. Once the crosslinking has been complete, e.g. in a photovoltaic module lamination process, the polymers that have cross-linked are no longer considered as thermoplastic materials. Therefore, in so far as the specification refers to photovoltaic modules after lamination, the described properties refer to the polymers prior to the lamination process, also including the cross-linked polymers.

The term melting point as referred to herein refers to the transition from a crystalline or semi-crystalline phase to a solid amorphous phase, also known as the crystalline melting temperature. The melting point of a polymer may be advantageously be determined by DSC. In the case of a block co-polymer, the term melting point herein refers to the temperature at which the higher melting block component will pass its glass transition temperature, thereby allowing the polymer to melt and flow. The “extrusion temperature” refers to the temperature to which a polymer material is heated during extruded, by means of a heated extruder and/or heated die.

Where to the melting temperature of a certain layer is referred, due to the fact that the layers are essentially composed of polymer materials with additives or optional other polymers only, this temperature will be largely determined by the melting temperature of the polymer material present in the layer. Accordingly, the melting temperature should be considered as the temperature of the polymer material present in the layer. The additives and/or optional polymers may be present in an amount of up to 25 wt %, based on the total weight of the main polymer in a layer, provided that the inclusion of such additives and/or optional polymers does not adversely affect the melt flow index In the film according to the invention wherein one or more of (a), (b) and (c) are preferably transparent. Where the film is to be employed on the backside of a photovoltaic cell, the preferably at least one of layers (b) or (c) is opaque.

The one or more opaque layer(s) preferably comprises diffuse reflective pigments, and has a reflective efficiency of at least 75% for light with a wavelength in the range of from 400 to 800 nm, as determined according to ASTM standard E 903, at an opaque layer thickness of from 50 to 500 μm. Preferably, at a total opaque layer thickness of 450 to 500 pm a reflective efficiency of 95%, or more for light with a wavelength in the range of from 400 to 800 nm, as determined according to ASTM standard E 903, preferably may be obtained.

The present invention preferably relates to a film, wherein layer (c) comprises an optionally hydrogenated polystyrene block copolymer with butadiene, isoprene and/or butylenes/ethylene copolymers (SIS, SBS and/or SEBS); a polymethacrylate polyacrylate block copolymer, a polyolefin, an olefin copolymer with copolymerizable functionalised monomers such as methacyrylic acid (ionomer). The term “ionomer” herein refers to a polymer that is typically obtained by partially or fully neutralizing the carboxylic acid groups of an ethylene/carboxylic acid copolymer, with one or more ion-containing bases.

The layers (a) to (c) may comprise two or more thermoplastic polymeric materials, each of which has (i) a melting temperature of from 80° C. to 165° C., preferably of from 85° C. to 155° C.

Suitable polymers include polyolefins, including polyethylenes such as ethylene homopolymers and ethylene copolymers, and polypropylenes such as propylene homopolymers and propylene copolymers; polyurethanes, polyvinyl butyrals, and combinations of two or more thereof. Suitable ethylene copolymers include those comprising copolymerized units of ethylene and a polar monomer. Suitable polar monomers may include, but are not limited to, vinyl acetate, carboxylic acids such as (meth)acrylic acids (including esters thereof (i.e., acrylates) and salts thereof (i.e., ionomers)), and combinations of two or more thereof. Where an ethylene homopolymer is employed, this may be a low density polyethylene, linear low density polyethylene, very low density polyethylene, ultra low density polyethylene, medium density polyethylene, high density polyethylene, metallocene catalyzed polyethylene, other polyethylenes that are the products of single-site catalysis, and combinations of two or more of these polyethylenes.

The layers (a) to (c) may advantageously comprise an ethylene/vinyl acetate copolymer (EVA copolymer) comprising copolymerized units of ethylene and vinyl acetate.

The content ratio of a constituent unit derived from vinyl acetate in the ethylene vinyl acetate co-polymer employed in layers (a) to (c) is advantageously 18% by mass or more.

An outer polymer layer (a) and/or (c) preferably has a melting point T₁ which at least 10° C. below the melting point T₂ of at least one of the remaining polymer layers. Preferably, the melting point T₁ is between 10 and 100° C. lower than the melting point T₂, more preferably between 10 and 50° C. lower.

In a preferred embodiment, at least one of polymer layers (a) and (c) have a melting point of at least 10° C. lower than the melting point of layer (b), more preferably 15, yet more preferably 25° C.

In a preferred embodiment, at least one of polymer layers (a) and (c) have a melting point of at least 100° C. lower than the melting point of layer (b), more preferably 85° C., yet more preferably 75° C., again more preferably 70, 65, 55, 50° C.

Preferably, the melt flow index of layer (b) at the extrusion temperature T_{b} of layer (b) is equal to or in the range of from −2 to plus 2 MFI to the MFI of layers (a) and/or (c) at the extrusion temperature Tₐ or T_{c} of layers (a) and/or (c). More preferably, the MFI of layer (b) differs in a range of from 0.5 to 10 from the MFI of layer (a) and/or (c) at a temperature T_{L} , wherein T_{L} is the lamination temperature of a vacuum lamination for solar panels comprising the film, and wherein T_{L} , T_{b}>Tₐ, T_{c}. T_{L} may be or to T_{b}.

Typical temperatures for the lamination are in the range of from 135 to 165° C., preferably 145 to 155° C.

Preferably, the MFI of the layers (a) and/or (c) is higher than the MFI of layer (b) at T_{L}.

This is beneficial as the encapsulation is more effective when the polymers are more liquid to wet the photovoltaic cell components.

The EVA copolymer may have a melt flow index rate (MFI) in the range of from 0.1 to 1000 g/10 minutes, preferably of from 0.3 to 300 g/10 minutes, yet more preferably of from 0.5 to 50 g/10 minutes, as determined in accordance with ASTM D1238 at 190° C. and 2.16 kg. The EVA copolymer may be a single EVA copolymer or a mixture of two or more different EVA copolymers. By different EVA copolymer is meant that the copolymers having different comonomer ratios, and/or the weight average molecular weight and/or molecular weight distribution may differ. Accordingly the EVA copolymer may also comprise copolymers that have the same co-monomer ratios, but different MFI due to having different molecular weight distribution.

In a preferred embodiment, the EVA copolymers advantageously comprise further monomers other than ethylene and vinyl acetate, such as alkyl acrylates, whereby the alkyl moiety of the alkyl acrylate may contain 1 to 6 or 1 to 4 carbon atoms, and may be selected from methyl groups, ethyl groups, and branched or unbranched propyl, butyl, pentyl, and hexyl groups.

Exemplary alkyl acrylates include, but are not limited to, methyl acrylate, ethyl acrylate, i-butyl acrylate, and n-butyl acrylate. The polarity of the alkyl acrylate comonomer may be manipulated by changing the relative amount and identity of the alkyl group present in the comonomer. Similarly, a C₁-C₆ alkyl methacrylate comonomer may be used as a comonomer. Such comonomers include methyl methacrylate, ethyl methacrylate, i-butyl methacrylate, and n-butyl methacrylate.

The EVA compositions used according to the invention may further comprise one or more other optional polymers, such as, for example, polyolefins including ethylene homopolymers, propylene homopolymers, additional ethylene copolymers, and propylene copolymers; ethylene (meth)acrylic copolymers. The optional polymers may be present in an amount of up to 25 wt %, based on the total weight of the EVA copolymer, provided that the inclusion of such optional polymers does not adversely affect the desirable performance characteristics of the EVA copolymer, such as the transparency, melt flow index, pigment dispersion and/or adhesion properties.

The EVA copolymers used herein may also contain other additives known within the art. The additives may include processing aids, flow enhancing additives, lubricants, dyes, flame retardants, impact modifiers, nucleating agents, anti-blocking agents such as silica, thermal stabilizers, UV absorbers, UV stabilizers, dispersants, surfactants, chelating agents, coupling agents, reinforcement additives, such as glass fibre, fillers and the like.

Generally, additives that may reduce the optical clarity of the EVA copolymer, such as reinforcement additives and fillers, are preferably present in layers (a) (b) and/or (c) where the film is to be employed as a backside encapsulant/Pigments or fillers suitable for use in the opaque, preferably diffuse reflective layer of the multilayer film include, but are not limited to, fillers having a refractive index of 1.4 or above, 1.6 or above, or 2 or above, or 2.5 or above, and a mean particle size of 0.1 to 20 μm, or 0.1 to 10 μm, or 0.1 to 5, or 0.1 to 2, or 0.2 to 1 μm, or 0.1 to 0.5 μm, or 0.2 to 0.5 μm. Specific examples of suitable fillers include, without limitation, calcium carbonate, magnesium carbonate, barium carbonate, magnesium sulphate, barium sulphate, calcium sulphate, zinc oxide, magnesium oxide, calcium oxide, titanium oxide, alumina, aluminum hydroxide, hydroxyapatite, silica, mica, talc, kaolin, clay, glass powder, asbestos powder, zeolite, clay silicate, coal fly ash, and combinations thereof.

Preferably, the filler is selected from materials that have refractive indices of 1.6 or greater, such as calcium carbonate, barium sulphate, titanium oxide, zinc oxide, mica, glass powder, and combinations hereof. In another reflecting layer, the filler is titanium oxide, which has a refractive index of 2.5, 2.7 or greater. Suitable grades of titanium oxide are well known.

Thermal stabilizers can be used and have been widely disclosed within the art. Any known thermal stabilizer may find utility within the compositions useful in the invention. Preferable general classes of thermal stabilizers include, but are not limited to, phenolic antioxidants, alkylated monophenols, alkylthiomethylphenols, hydroquinones, alkylated hydroquinones, tocopherols, hydroxylated thiodiphenyl ethers, alkylidenebisphenols, O-, N- and S-benzyl compounds, hydroxybenzylated malonates, aromatic hydroxybenzyl compounds, triazine compounds, aminic antioxidants, aryl amines, diaryl amines, polyaryl amines, acylaminophenols, oxamides, metal deactivators, phosphites, phosphonites, benzylphosphonates, ascorbic acid (vitamin C), compounds that destroy peroxide, hydroxylamines, nitrones, thiosynergists, benzofuranones, indolinones, and the like and mixtures thereof. The EVA copolymer may contain any effective amount of thermal stabilizers. Use of a thermal stabilizer is optional and in some instances is not preferred. When thermal stabilizers are used, the polymer materials typically contains at least 0.05 wt %, and up to 10 wt %, more preferably up to 5 wt %, and most preferably up to 1 wt %, of thermal stabilizers, based on the total weight of the polymer.

UV absorbers may preferably be used and have also been widely disclosed within the art. Any known UV absorber may find utility within the present invention, provided it is compatible with the film system and does not adversely affect properties or processability. Preferable general classes of UV absorbers include, but are not limited to, benzotriazoles, hydroxybenzo-phenones, hydroxyphenyl triazines, esters of substituted and unsubstituted benzoic acids, and the like and mixtures thereof. The polymer material may contain any effective amount of UV absorbers. Use of a UV absorber is optional and in some instances is not preferred. When UV absorbers are utilized, the polymer contains at least 0.05 wt %, and up to 10 wt %, more preferably up to 5 wt %, and most preferably up to 1 wt %, of UV absorbers, based on the total weight of the polymer.

Particularly preferred are hindered amine light stabilizers (HALS), which are widely disclosed within the art. Generally, hindered amine light stabilizers are disclosed to be secondary, tertiary, acetylated, N-hydrocarbyloxy substituted, hydroxy substituted, or other substituted cyclic amines which are characterized by a substantial amount of steric hindrance, generally derived from aliphatic substitution on the carbon atoms adjacent to the amine function. The polymer may preferably contain any effective amount of hindered amine light stabilizers. Use of hindered amine light stabilizers is optional and in some instances is not preferred.

When hindered amine light stabilizers are used, the polymer contains at least 0.05 wt %, and up to 10 wt %, more preferably up to 5 wt %, and most preferably, up to 1 wt %, of hindered amine light stabilizers, based on the total weight of the polymer.

Silane coupling agents may be added to the polymer to improve its adhesive strength. Useful illustrative silane coupling agents include [gamma]-chloropropylmethoxysilane, vinylmethoxysilane, vinyltriethoxysilane, vinyltris([beta]-methoxyethoxy)silane,[gamma]-vinylbenzylpropylmethoxy-silane, N-[beta]-(N-vinylbenzylaminoethyl)-[gamma]-aminopropyl-trimethoxysilane, [gamma]- methacryloxypropyltriethoxysilane, [gamma]-methacryloxypropyltrimethoxysilane, [gamma]-methacryloxypropyltriethoxysilane, vinyltriacetoxysilane, [gamma]-glycidoxypropyltrimethoxysilane, [gamma]-glycidoxypropyltriethoxysilane, [beta]-(3,4-epoxycyclohexyl)ethylthmethoxysilane, vinylthchlorosilane, [gamma]-mercaptopropylmethoxysilane, [gamma]-aminopropyltriethoxysilane, N-[beta]-(aminoethyl)-[gamma]-aminopropyltrinethoxysilane, and/or mixtures of two or more thereof.

The silane coupling agents are preferably incorporated in the encapsulant layer at a level of 0.01 to 5 wt %, or more preferably 0.05 to 1 wt %, based on the total weight of the polymer.

The film materials according to the present invention further preferably comprises one or more organic peroxides, which enables to crosslink the ethylene-vinyl acetate copolymer, thereby increasing the adhesion strength, humidity resistance and penetration resistance, while maintaining a high transparency, if so desired.

Any organic peroxides that are decomposed at a temperature of at least 110° C. to generate radicals may advantageously be employed as the above-mentioned organic peroxide.

The organic peroxide or combination of peroxides are generally selected in the consideration of film-forming temperature, conditions for preparing the composition, curing (bonding) temperature, heat resistance of body to be bonded and storage stability.

According to a preferred embodiment of the subject invention, the peroxide is chosen such that it does essentially no decompose the resin processing temperature, in particular during coextrusion and/or a further extrusion and pelletizing step, while is only activated at the solar cell formation temperature.

“Essentially not decomposing” according to the present invention refers to a half-life of at least 0.1 to 1 hours at the coextrusion temperature.

Examples of the organic peroxides include 2,5-dimethylhexane-2,5- dihydroperoxide, 2,5-dimethyl-2,5-di(tert-butylperoxy)hexane, 3-di-tert-butylperoxide, dicumyl peroxide, 2,5-dimethyl-2,5-di(2-ethylhaxanoylperoxy)hexane, 2,5-dimethyl-2,5-di(tert-butylperoxy)hexane, tert-butylcumylperoxide, [alpha],[alpha]′-bis(tert-butylperoxyisopropyl)benzene, [alpha],[alpha]′-bis(tert-butylperoxy)diisopropylbenzene, n-butyl-4,4-bis(tert-butylperoxy)butane, 2,2-bis(tert-butylperoxy)butane, 1,1-bis(tert-butylperoxy)cyclohexane, 1,1-bis(tert-butylperoxy)-3,3,5-trimethylcyclohexane, tert-butylperoxybenzoate, benzoyl peroxide, and 1,1-di (tert-hexylperoxy)-3,3,5-trimethylcyclohexane. Of these, 2,5-dimethyl-2,5-di(2-ethylhexanoylperoxy)hexane, and 1,1-di (tert-hexylperoxy)-3,3,5-trimethylcyclohexane are particularly preferred.

The content of the organic peroxide in the film layers is preferably in the range of 0.1 to 5 parts by weight, more preferably in the range of 0.2 to 1.8 parts by weight based on 100 parts by weight of polymer.

The film of the present invention may further contain crosslinking auxiliary agents, if so required. Cross-linking auxiliary agents herein are understood as compounds providing at least one, preferably several radically polymerizable functional groups. The crosslinking auxiliary agent typically increases the gel fraction of ethylene-vinyl acetate copolymer, thereby improving the durability and mechanical properties of the encapsulant. Crosslinking auxiliary agents are typically employed in an amount of 10 parts by weight or less, preferably in the range of 0.1 to 5.0 parts by weight, based on 100 parts by weight of polymer. Examples of the cross-linking auxiliary agents comprise tri-functional cross-linking auxiliary agents such as triallyl cyanurate and triallyl isocyanurate, and mono- or di-functional crosslinking auxiliary agents of (meth)acryl esters. Among these compounds, triallyl cyanurate and triallyl isocyanurate are particularly preferred.

The films according to the present invention may be employed advantageously for front- and/or backside encapsulation.

According to the present invention, “front side” corresponds to a side of the photovoltaic element or cell irradiated with light, i.e. the light-receiving side, whereas the term “backside” corresponds to the reverse side of the light-receiving side of the photovoltaic elements.

For the use as front side encapsulants, the layers (a) to (c) are preferably transparent. For the back side encapsulant, layers (a) to (c) may be opaque, but preferably only (b) and (c) are opaque.

Where the film is to employed as front encapsulant, preferably a luminescence downshifting compound is present in layers (a) to (c) , which luminescence downshifting compound has the property that it can absorb at least partially radiation at a lower wavelength that the luminescence downshifting compound present in a next layer. Thus the barrier layer will comprise luminescence downshifting compound or compounds which will absorb radiation at a lower wavelength than the luminescence downshifting compound(s) in the remaining polymer layer(s). This is advantageous because many organic compounds are sensitive to especially the shorter wavelength radiation. By filtering said shorter wavelength radiation and re-emitting longer wavelength radiation a more stable polymer sheet is obtained. More preferably a first polymer layer, i.e. barrier layer, has the property that it can absorb at least partially UV radiation, suitably between 10 and 400 nm, and re-emit radiation at a higher wavelength. The luminescence downshifting compound(s) which absorb in this UV wavelength may be combined with traditional UV stabilizers. It is preferred to limit the use of such classic stabilizers because they transform the absorbed UV radiation into thermal energy rather than re-emitting the radiation at the longer wavelengths. Thus a more efficient polymer sheet is obtained when such UV stabilizers are omitted or used in a low concentration. The luminescence downshifting compound will then take over the protective function of the UV stabilizer.

The encapsulant film according to the invention, when used as front sheet, preferably may also comprise compounds that convert the shorter wavelength radiation of sunlight to longer wavelength radiation having a wavelength range in which photovoltaic cells convert radiation into electricity more effectively. The invention is thus also directed to the use of the encapsulant film according to the invention for enhancing the performance of a photovoltaic cell by luminescent down-shifting of sunlight.

The first transparent polymer encapsulant layer (b) preferably comprises a luminescence downshifting compound for at least partially absorbing radiation having a certain wavelength and re-emitting radiation at a longer wavelength than the wavelength of the absorbed radiation. Such compounds may improve the efficiency of a solar panel. The photovoltaic cell typically operates optimally in a certain wavelength range. By shifting part of the lower wavelength radiation of the sun into the desired wavelength range at which the PV cell works optimally it is possible to improve the efficiency.

The luminescence downshifting compound may be an organic or inorganic luminescent compound, which are capable of partially absorbing radiation having a certain wavelength and re-emitting radiation at a longer wavelength than the wavelength of the absorbed radiation. Such compounds are known and for example described by Efthymios Klampaftis, David Ross, Keith R. McIntosh, Bryce S. Richards, Enhancing the performance of a solar cell via luminescent down-shifting of incident spectrum, a review, Solar Energy Materials & Solar Cells 93 (2009) 1182-1194.

Suitable organic luminescence downshifting compound are for example laser dyes. The following compounds, of which some are also used as a laser dye, may find application as an organic luminescence downshifting compound: Rhodamine, for example 5-carboxytetramethylrhodamine, Rhodamine 6G, Rhodamine B, Rubrene, aluminium tris-([delta]-hydroxyquinoline (Alq3), N,N′-diphenyl-N,N′-bis-(3-methylphenyl)-1,1′-biphenyl- 4-4′-diamine (TPD), bis-(8-hydroxyquinoline)-chlorogallium (Gaq2Cl); a perylene carbonic acid or a derivative thereof; a naphthalene carbonic acid or a derivative thereof; a violanthrone or an iso-violanthrone or a derivative thereof. Examples of organic luminescence downshifting compound are quinine, fluorescien, sulforhodamine 5-Bis(5-tert-butyl-2-enzoxazolyl)thiophene, Nile Blue.

Other examples of suitable organic luminescence downshifting compounds are Coumarin dyes, for example 7-Diethylaminocoumarin-3-carboxylic acid hydrazide (DCCH), 7-Diethylaminocoumarin-3-carboxylic acid succinimidyl ester, 7-Methoxycoumarin-3-carboxylic acid succinimidyl ester, 7-Hydroxycoumarin-3-carboxylic acid succinimidyl ester, 7-Diethylamino-3-((((2-iodoacetamido)ethyl)amino)carbonyl)coumarin (IDCC), 7-Diethylamino-3-((((2-maleimidyl)ethyl)amino)carbonyl)coumarin (MDCC), 7-Dimethylamino-4-methylcoumarin-3-isothiocyanate (DACITC), N-(7-Dimethylamino-4-methylcoumarin-3-yl)maleimide (DACM), N-(7-Dimethylamino-4-methylcoumarin-3-yl)iodoacetamide (DACIA), 7-Diethylamino-3-(4-maleimidylphenyl)-4-methylcoumarin (CPM), 7-Diethylamino-3-((4-(iodoacetyl)amino)phenyl)-4-methylcoumarin (DCIA), 7-Dimethylaminocoumarin-4-acetic acid (DMACA) and 7-Dimethylaminocoumarin-4-acetic acid succinimidyl ester (DMACASE).

Other examples of suitable organic luminescence downshifting compounds are perylene dyes, for example N, N′- Bis(2,6-diisopropylphenyl)perylene-3,4:9,10-tetracarbonic acid diimide, N,N′-Bis(2,6-dimethylphenyl)perylene-3,4:9,10-tetracarbonic acid diimide, N,N′-Bis(7-tridecyl)perylene-3,4:9,10-tetracarbonic acid diimide, N,N′-Bis(2,6-diisopropylphenyl)-1,6,7,12-tetra(4-tert-octylphenoxy)perylene-3,4:9,10-tetracarbonic acid diimide, N, N′- Bis(2,6-diisopropylphenyl)-1,6,7,12-tetraphenoxyperylene-3,4:9,10-tetracarbonic acid diimide, N,N′-Bis(2,6-diisopropylphenyl)-1,6- and -1,7-bis(4-tert-octylphenoxy)perylene-3,4:9,10-tetracarbonic acid diimide, N,N′-Bis(2,6- diisopropylphenyl)-1,6- and -1,7-bis(2,6-diisopropylphenoxy)-perylene-3,4:9,10-tetracarbonic acid diimide, N-(2,6-diisopropylphenyl)perylene-3,4-dicarbonic acid imide, N-(2,6-diisopropylphenyl)-9-phenoxyperylene-3,4-dicarbon acid imide, N-(2,6-diisopropylphenyl)-9-(2,6-diisopropylphenoxy)perylene-3,4-dicarbonic acid imide, N-(2,6-diisopropylphenyl)-9-cyanoperylene-3,4-dicarbonic acid imide, N-(7-tridecyl)-9- phen-oxyperylene-3,4-dicarbonic acid imide, perylene-3,9- and -3,10-dicarbonic acid diisobutyl-ester, 4,10-dicyanoperylene-3,9- and 4,9-dicyanoperylene-3,10-dicarbonic acid diisobutyl-ester and perylene-3,9- and -3,10-dicarbonic acid di(2,6- diisopropylphenyl)amide.

Perylene dyes usually absorb radiation in the wavelength region of 360 to 630 nm and re-emit between 470 to 750 nm. Besides perylene dyes, other fluorescent dyes having similar structures may be employed, such as dyes on the basis of violanthrones and/or iso-violanthrones, such as the structures disclosed in EP-A-073 007. As a preferred example of well suited compounds are alkoxylated violanthrones and/or iso-violanthrones, such as 6,15-didodecyloxyisoviolanthronedion-(9,18). Other examples of suitable organic luminescence downshifting compounds are naphthalene type compounds. These dyes typically exhibit an absorption within the UV range at wavelengths of about 300 to 420 nm and exhibit an emission range at about 380 to 520 nm. Examples of naphthalene type compounds are the naphthalene carbonic acid derivatives, for example naphthalene 1,8:4,5-tetracarbonic acid diimides, and especially naphthalene-1,8-dicarbonic acid imides, most preferably 4,5-dialkoxynaphthalene-1,8-dicarbonic acid monoimides and 4-phenoxynaphthalene-1,8-dicarbonic acid monoimides. Other naphthalene type compounds are for example N-(2-ethylhexyl)-4,5-dimethoxynaphthalene-1,8-dicarbonic acid imide,

N- (2,6-diisopropyl-phenyl)-4,5-dimethoxynaphthalene-1,8-dicarbonic acid imide, N-(7- tridecyl)-4,5-dimethoxy-naphthalene-1,8 dicarbonic acid imide, N-(2,6- diisopropylphenyl)-4,5-diphenoxynaphthalene-1,8-dicarbonic acid imide and N, N′- Bis(2,6-diisopropylphenyI)-1,8:4,5-naphthalene tetracarbonic acid diimide.

Other examples are Lumogen F Yellow 083, Lumogen F Orange 240, Lumogen F Red 305 and Lumogen F Violet 570 as obtainable from BASF.

For example the following organic luminescence downshifting compounds are capable of absorbing (excitation wavelength) at 300 to 360 nm and have an emission spectrum with a maximum around 365 up to 400 Nm: diphenyloxazole (2,5-diphenyloxazol 1,4-Di[2-(5-phenyloxazolyl)benzene, 4,4′-diphenylstilbene, 3,5,3″″,5″″-tetra-t-butyl-p-quinquephenyl. These compounds can be obtained for example from Synthon Chemicals GmbH and

Luminescence Technology Corp. For example the following organic luminescence downshifting compounds are capable of re-emitting the incoming radiation emission towards 400-460 Nm: 2,5-thiopenediylbis(5-tert-butyl-1,3-benzoxale). For example the following organic luminescence downshifting compounds are capable of re-emitting the incoming radiation emission towards 560 nm: hostasole 3G naphtalimide (Clariant), Lumogen F Yellow 083 (BASF), Rhodamine 110 (Lambdachrome 5700).

For example the following organic luminescence downshifting compounds are capable of re-emitting the incoming radiation emission towards 580-640 nm: hostazole GG thioxanthene benzanthione (Clariant), -Lumogen F Red 300 (BASF), benzoic rhodamine 6G ethylaminoxanthene (Lambdachrome 5900),

For example the following organic luminescence downshifting compounds are capable of re-emitting the incoming radiation emission towards 640-680 nm: cretsyl purple diaminobenzole, Sublforhodamine B (Lambdachrome LC6200),

For example the following organic luminescence downshifting compounds are capable of re-emitting the incoming radiation emission towards 700-1000 nm: Rhodamine 800 (Sigma), Pyridine 2 (Lambdachrome LC7600), DOTC, HITC (Lambdachrome LC7880), Styril 9 (Lambdachrome LC8400).

Suitable inorganic luminescent compounds are semiconducting quantum dot materials and nanoparticles comprising Sm³⁺, Cr3+, ZnSe, Eu2+ and Tb3+ and nanoparticles comprising ZnO; ZnS doped with Mg, Cu, and/or F; CdSe; CdS; TiO2; Zr3+, Zr4+; and/or Eu3+, Sm3+, or Tb3+ doped YPO4. A common characteristic of these materials is that they are capable of exhibiting fluorescence. The nanoscale particles may be made by any suitable process, for example by the process as disclosed in U.S. Pat. No. 7,384,680. They may have an average diameter of less than 75 nm, more in particular they may have a size of between 3 and 50 nm as determined using Transmission electron microscopy (TEM). Possible Europium complexes suitable as luminescent compounds are [Eu(β-diketonate)3-(DPEPO)] and other Eu3+ complexes as described by Omar Moudam et al, Chem. Commun., 2009, 6649-6651 by the Royal Society of Chemistry 2009.

Another example of a suitable inorganic luminescent compound are molecular sieves comprising oligo atomic metal clusters include clusters ranging from 1 to 100 atoms of the following metals (sub nanometer size), Si, Cu, Ag, Au, Ni, Pd, Pt, Rh, Co and Ir or alloys thereof such as Ag/Cu, Au/Ni etc. The molecular sieves are selected from the group consisting of zeolites, porous oxides, silicoaluminophosphates, aluminophosphates, gallophosphates, zincophophates, titanosilicates and aluminosilicates, or mixtures thereof. In a particular embodiment of present invention the molecular sieves of present invention are selected from among large pore zeolites from the group consisting of MCM-22, ferrierite, faujastites X and Y. The molecular sieves in another embodiment of present invention are materials selected from the group consisting of zeolite 3 A, Zeolite 13X, Zeolite 4A, Zeolite 5 A and ZKF. Preferably the oligo atomic metal clusters are oligo atomic silver molecules containing 1 to 100 atoms. Illustrative examples of such molecular sieve based downshifting compounds are described in WO-A-2009006708, which publication is hereby incorporated by reference.

The concentration of the luminescence downshifting compound in layer (b) will depend on the chosen luminescence downshifting compound. Some compounds are more effective and will require a lower concentration in the polymer layer and some compounds will require a higher concentration because they are less efficient in absorbing and re-emitting radiation.

One or more layers (a) to (c) may comprise at least one luminescence downshifting compound. The polymer layer may comprise a single luminescence downshifting compound or more than one luminescence downshifting compound. If more than one luminescence downshifting compounds are present it is preferred that compounds are combined which absorb radiation at a different wavelength and re-emit radiation at a different longer wavelength. In this manner a so-called luminescence downshifting “cascade” may be obtained, wherein radiation re-emitted by one compound is absorbed by a next compound. Such a cascade is also referred to as a Photon-Absorption-Emitting Chain (PAEC).

In a preferred embodiment, the film comprises the following coextruded polymer sub-layers: a first polymer layer (a) comprises a luminescence downshifting compound for absorbing radiation at between 280 to 400 nm and re-emitting radiation at between 400 to 550 nm, another polymer sub-layer (b) comprises a luminescence downshifting compound for absorbing radiation at between 360 to 470 nm and re-emitting radiation at between 410 to 670 nm, and another polymer sub-layer (c) comprises a luminescence downshifting compound for absorbing radiation at between 360 to 570 nm and re-emitting radiation at between 410 to 750 nm.

One or more luminescence downshifting compounds may be present in one of the above sub-layers. Additional layers may be present in the polymer sheet, wherein the additional layers may also comprise luminescence downshifting compounds or other additives.

Examples of suitable luminescence downshifting compounds for layer (b1) are 2,5-diphenyloxazol (PPO diphenyloxazole), 4,4′-Diphenylstilbene (DPS), 1,4-Di[2-(5-phenyloxazolyl)benzene (POPOP), 3,5,3″″,5″″Tetra-t-butyl-p-quinquephenyl (QUI P-quinqaphenyl), 1,8-ANS (1-Anilinonaphthalene-8-sulfonic acid), 1-Anilinonaphthalene-8-sulfonic acid (1,8-ANS), 6,8-Difluoro-7-hydroxy-4-methylcoumarin pH 9.0, 7-Amino-4-methylcoumarin pH 7.0, 7-Hydroxy-4-methylcoumarin, 7-Hydroxy-4-methylcoumarin pH 9.0, Alexa 350, BFP (Blue Fluorescent Protein), Cascade Yellow, Cascade Yellow antibody conjugate pH 8.0, Coumarin, Dansyl Cadaverine, Dansyl Cadaverine, MeOH, DAPI, DAPI-DNA, Dapoxyl (2-aminoethyl) sulphonamide, DyLight 350, Fura-2 Ca2+, Fura-2, high Ca, Fura-2, no Ca, Hoechst 33258, Hoechst 33258-DNA, Hoechst 33342, Indo-1, Ca free, LysoSensor Yellow pH 3.0, LysoSensor Yellow pH 9.0, Marina Blue, Sapphire, and/or SBFI-Na+.

Examples of suitable luminescence downshifting compounds for sub-layer (b) are: 7-Diethylaminocoumarin-3-carboxylic acid hydrazide (DCCH), 7-Diethylaminocoumarin-3-carboxylic acid succinimidyl ester, 7-Methoxycoumarin-3-carboxylic acid succinimidyl ester, 7-Hydroxycoumarin-3-carboxylic acid succinimidyl ester, 7-Diethylamino-3-((((2-iodoacetamido)ethyl)amino)carbonyl)coumarin (IDCC), 7-Diethylamino-3-((((2-maleimidyl)ethyl)amino)carbonyl)coumarin (MDCC), 7-Dimethylamino-4-methylcoumarin-3-isothiocyanate (DACITC), N-(7-Dimethylamino-4-methylcoumarin-3-yl)maleimide (DACM), N-(7-Dimethylamino-4-methylcoumarin-3-yl)iodoacetamide (DACIA), 7-Diethylamino-3-(4′-maleimidylphenyl)-4-methylcoumarin (CPM), 7-Diethylamino-3-((4′-(iodoacetyl)amino)phenyl)-4-methylcoumarin (DCIA), 7-Dimethylaminocoumarin-4-acetic acid (DMACA), 7-Dimethylaminocoumarin-4-acetic acid succinimidyl ester (DMACASE), Acridine Orange, Alexa 430, Alexa Fluor 430 antibody conjugate pH 7.2, Auramine O, Di-8 ANEPPS, Di-8-ANEPPS-lipid, FM 1-43, FM 1-43 lipid, Fura Red Ca2+, Fura Red, high Ca, Fura Red, low Ca, Lucifer Yellow and/or CH, SYPRO Ruby (CAS 260546-55-2).

Examples of suitable luminescence downshifting compounds for sub-layer (c) are the above compounds illustrated for layer (b) and Rhodamine 110, Rhodamine 6G ethylaminoxanthene benzoique (obtainable from Lambdachrome), Alexa Fluor 647 R-phycoerythrin streptavidin pH 7.2, Ethidium Bromide, Ethidium homodimer, Ethidium homodimer-1-DNA, FM 4-64, FM 4-64, 2% CHAPS, Nile Red-lipid and/or Propidium Iodide.

An example of another possible cascade may comprise a first luminescence downshifting compound with an absorption range located at approximately 280 nm tot 365 nm and with an emission range located at approximately 380 nm to 430 nm. An example of a suitable luminescence downshifting compound is 3,5,3″″,5″″-tetra-t-butyl-p-quinquephenyl, known to have a maximum absorption at approximately 310 nm and a maximum emission at approximately 390 nm. This luminescence downshifting compound may be added at a concentration of for example around 33% of the total content of luminescence downshifting compounds in the polymer layer. A second luminescence downshifting compound with an absorption range located at approximately 335 to 450 nm and with an emission range located at approximately 410 up to 550 nm. An example of a suitable luminescence downshifting compound is 2,3,5,6-1H,4H- tetrahydroquinolizino-[9,9a,1-gh]-coumarin, with a maximum excitation wavelength at approximately 396 nm and a maximum emission wavelength at approximately 490 nm in a concentration of for example around 33% of the total content of luminescence downshifting compounds in the polymer layer. A third luminescence downshifting compound of the cascade may have an absorption range located at approximately 450 nm tot 550 nm and with an emission range located at 560 nm till 700 nm. An example of a suitable luminescence downshifting compound is 1-amino-2-methylantraquinone with a maximum absorption around 450 nm and a maximum emission at approximately 600 nm in a concentration of for example around 33% of the total content of luminescence downshifting compounds in the polymer layer. By providing luminescent downshifting compound which can absorb radiation in the UV wavelength range in one of the sub-layers of the film and preferably the layer which is closest to the incident light a more stable and more efficient solar panel is obtained. This is especially the case when the film comprises an EVA copolymer. The EVA copolymer may degrade under the influence of UV radiation. By providing UV absorbers the lifetime of the EVA copolymer is typically improved. UV absorbers however convert the UV radiation into heat. This results in that photons having a wavelength in the UV range are not effectively used to generate electricity by means of the photovoltaic effect.

The efficiency of the solar panel which comprises the film comprising the EVA copolymer may be improved by adding a luminescent downshifting compound or a cascade of compounds which absorbs radiation in the UV wavelength range and emits radiation at a higher wavelength. By using a luminescent downshifting compound which can absorb radiation in the UV wavelength range and emit at a higher wavelength range the UV light is converted into radiation which is less harmful for the polymer and which can be effectively used to generate electricity by means of the photovoltaic effect. Thus a solar panel is obtained which is more efficient and requires less or no UV absorber.

The total concentration of the down conversion blend in the polymer matrix depends on the thickness of the film as the efficient down conversion is function of the amount of molecules the incident light will encounter per volume. A polymer layer of approximately 400 to 450 μm may for example be doped with the constituting luminescence downshifting compounds in the range of 200 up to 1000 ppm. A suitable polymer layer of 450 μm with a good balance of UV blocking and transmission was for example obtained at a concentration of the constituting luminescence downshifting compounds of approximately 500 ppm in the final polymer layer. The photovoltaic front sheet preferably is a glass substrate such as a low iron silicate glass. The thickness of the glass substrate is generally in the range of 0.1 to 10 mm, preferably 0.3 to 5 mm. The glass substrate can be chemically or thermally tempered.

The present invention further relates to a process for the preparation of photovoltaic modules, wherein photovoltaic cells or elements are encapsulated between a transparent front side protection material and a backside protection material so that a fully encapsulated structure is obtained.

Typically, the front sheet, the encapsulant film, the cells with ribbons and connectors, the back encapsulant and a backsheet, or an encapsulant integrated multilayer backsheet are placed with the front sheet upside down, and are then introduced into a vacuum laminator, and finally pressure bonded under conversion heating at a temperature in the range of from of 115 to 175°, preferably 140 to 165° C., most preferably from 145 to 155° C. The laminate is preferably also subjected to degassing or a time period of 0.1 to 8 minutes.

Thereafter, the sealing film is cross-linked and/or cured by application of heating and pressure.

The compression lamination pressure preferably is in the range of from of 0.1 to 1.5 kg/cm². The lamination time typically is in the range of from 5 to 15 minutes. This heating enables the ethylene-vinyl acetate copolymer contained in the front and back encapsulant to crosslink, whereby the photovoltaic elements, the transparent front sheet and the backsheet are strongly adhered to seal the photovoltaic module.

A preferred embodiment of the present invention resides in a film wherein layer a) is transparent, while layer (b) is an opaque, preferably white pigmented reflective layer acting as a diffuse reflector. This allows to overcome a particular problem with monolayer diffuse reflector pigment containing polymer layers as back encapsulants, which tend to overflow onto front-side of the cell during the lamination process.

The film, when employed as backside encapsulant, is preferably combined with a single or mulitlayer backsheet comprising a film substrate material selected from polyesters or fluorine-containing polymers. This may be a single layer, or preferably multiple layers of polyester and a single layer or multiple layers of fluorine-containing polymer, for example, a laminated film of two or multiple layers of polyester and a layer of a fluorine containing polymer.

Accordingly, the backsheet film substrate may advantageously be selected from (i) partly aromatic polyesters, (ii) fluorine-containing polymers; (iii) polyesters or fluorine-containing polymers with a coat of metal or metal oxide/non-metal oxide on the surface; or (iv) a laminated film made from two or more materials found above. The polyester preferably is a partly aromatic polyester. This polyester preferably comprises polymers selected from the group consisting of polymeric C₂ to C₆ alkylene phthalates, polymeric C₂ to C₆ alkylene naphthalates, and mixtures or blends thereof, such as polyethylene terephthalate (PET), polyethylene 2,5-furane dicarboxylic acid ester (PEF), polytrimethylene terephthalate, polybutylene terephthalate, polyhexylene terephthalate, polyethylene o-phthalate, polytrimethylene o-phthalate, polybutylene o-phthalate, and polyhexylene o-phthalate, preferably polyethylene terephthalate; polymeric C₂ to C₆ alkylene naphthalates, preferably polymeric C₂ to C₄ alkylene naphthalates, such as polyethylene naphthalate, polytrimethylene naphthalate, and polybutylene naphthalate; and copolymers and blends of two or more above materials. Alternatively, the backside encapsulant may be combined with a glass backsheet.

Suitable polyester substrates may be formed by film-casting and then treating by biaxial orientation to further improve mechanical strength and gas barrier properties. Such films are known for their good mechanical, dielectric, and gas barrier properties.

The fluorine-containing polymers may be any suitable fluorine-containing polymer known in the art, including polymers of fluoroethylene; vinylidene fluoride; chlorotrifluoroethylene; tetrafluoroethylene; and copolymers of any of the above with other non-fluorinated, partially or fully fluorinated monomers, such as ethylene, propylene, fluoroethylene, ethylene fluoride, vinylidene fluoride, chlorotrifluoroethylene, hexafluoropropylene, tetrafluoroethylene, perfluoroalkoxyvinyl ether, and perfluoropropylene.

The backsheet film may be a single or a multiple layer, e.g. a laminated film of double-layer or multi-layer fluorine-containing polymer. The total thickness of the fluorine-containing polymer substrate layer is preferably in the range of from 10 to 350 μm, more preferably in the range of from 15 to 300 μm, and most preferably in the range of from 20 to 250 μm.

Additional layers may be present, such as metal or metal oxide layers, which may be laminated or deposited by a suitable process, such as chemical or physical vapour deposition. In order to increase the bonding strength between the substrate and the bonding layer, the substrate surface may be surface-treated. There are no restrictions to suitable surface treatment methods, which may be any conventional methods known in the art. For example, it may be a corona treatment, flame treatment, or primer treatment.

Non-restrictive examples of suitable primers include, for example, imine primers and amine primers. When primer treatment is used for surface treatment of the substrate surface, there are no specific restrictions to the final thickness of the formed primer, which may be any thickness commonly used in the art, as long as the primer does not adversely affect the bonding strength between the polyester substrate and the encapsulant layer. Other layers may be present, e.g. a polyolefinic layer acting as additional gas and water vapour barrier layers.

The encapsulant films or sheets according to the invention may be produced by any suitable process, for example, through dipcoating, solution casting, compression molding, injection molding, lamination, melt extrusion casting, blown film processes, extrusion coating, tandem extrusion coating, or by any other procedures that are known to those of skill in the art. Preferably, though the sheet is formed by melt coextrusion casting, melt extrusion coating, blown film processes, or tandem melt extrusion coating processes.

Preferably, layer (a) and (c) comprises virgin material. Applicants found , however, that intermediate layers and layers that are not in direct contact with a glass substrate or photovoltaic cell substrate, layer (s (b) and/or (c) may comprise at least in part recycled material. The term “virgin” material herein relates to material that has not been employed in a photovoltaic cell lay-up process. The term “recycled” material relates to material that has been employed in a film formation and subsequently has been trimmed off, or film ends or other unused parts of the film.

Such films can typically not be used again for the same purpose, but are usually considered as “waste” materials since the active silane composition at the surface is usually not sufficiently high to ensure sufficient bonding with the surface of the front or backsheet, and/or the components to be encapsulated.

Layer (b), where at least in part composed of an EVA copolymer and/or layer (c) in the case of backside encapsulant according to the present invention therefore preferably comprises at least in part of ethylene vinyl acetate material that was removed from the film after the production process, when sizing the film for the photovoltaic module production during an encapsulation process for photovoltaic cells, and subsequently pelletized. The thus pelletized material is then preferably returned to the coextrusion process for the formation of layers (b) and/or (c), respectively.

The pelletisation process advantageously involves an extrusion at a low temperature, i.e. a temperature below the activation temperature of any peroxide activator, followed by a low temperature pellet formation process. More preferably, the process involves a so-called under water pelletisation process. Layer (b) and/or (c) preferably hence comprises more hydrolysed silane components than layers (a) and/or (c). Accordingly, the present invention also preferably relates to a film wherein layer (b) and/or (c) comprises at least in part of ethylene vinyl acetate material that was removed from the film prior to an encapsulation process for photovoltaic cells, and subsequently pelletized.

Layer (b) may alternatively comprise a polymethyl metacrylate n-butylacrylate block copolymer, as disclosed in WO2012057079, and commercially available as “Kurarity” from Kuraray Corp.

A further preferred embodiment comprises a polyolefin in layer (b), preferably a polyethylene or polypropylene, such as an LDPE type. The benefit of this layer is the high barrier properties, as well as the fact that the crimp due to annealing of the EVA layer(s) is further reduced.

Polyolefins, such as polyethylene and polypropylene suitable for the layer (b) include high density polyethylene, medium density polyethylene, low density polyethylene, linear low density polyethylene, metallocene-derived low density polyethylene, and polypropylene copolymer. Low density polyethylene, and polypropylene copolymers having a suitably high MFI and a melt temperature at in the range of from 135 to 155° C.

Layer (b) may also comprise polymers selected from poly(meth)acrylates, polyepoxides, polyurethanes, functionalized polyolefins, e.g. on the basis of EPM or EPDM rubbers, silicones and/or ionomers, nd/or combinations thereof.

Suitable polyolefin copolymer materials include ethylene-C₁ to C₄ alkyl (meth)acrylate copolymers, for example, ethylene-methyl methacrylate copolymers, ethylene-methyl acrylate copolymers, ethylene-ethyl methacrylate copolymers, ethylene-ethyl acrylate copolymers, ethylene-propyl methacrylate copolymers, ethylene-propyl acrylate copolymers, ethylene-butyl methacrylate copolymers, ethylene-butyl acrylate copolymers, and mixtures of two or more copolymers thereof, wherein copolymer units resulting from ethylene account for 50% to 99%; preferably 70% to 95%, by total weight of each copolymer; ethylene-methacrylic acid copolymers, ethylene-acrylic acid copolymers and blends thereof, wherein copolymer units resulting from ethylene account for 50 to 99%, preferably 70 to 95%, by total weight of each copolymer; ethylene-maleic anhydride copolymers, wherein copolymer units resulted from ethylene account for 50 to 99%, preferably 70 to 95%, by total weight of the copolymer; polybasic polymers formed by ethylene with at least two co-monomers selected from C₁ to C₄ alkyl methacrylate, C₁ to C₄ alkyl acrylate, ethylene-methacrylic acid, ethylene-acrylic acid and ethylene-maleic anhydride, non-restrictive examples of which include, for example, terpolymers of ethylene-methyl acrylatemethacrylic acid, wherein copolymer units resulting from methyl acrylate account for 2 to 30% by weight and copolymer units resulting from methacrylic acid account for 1 to 30% by weight, terpolymers of ethylene-butyl acrylatemethacrylic acid, wherein copolymer units resulting from butyl acrylate account for 2 to 30% by weight and copolymer units resulting from methacrylic acid account for 1 to 30% by weight, terpolymers of ethylene-propyl methacrylateacrylic acid, wherein copolymer units resulting from propyl methacrylate account 15 for 2 to 30% by weight and copolymer units resulting from acrylic acid account for 1 to 30% by weight, terpolymers of ethylene-methyl acrylate-acrylic acid, wherein copolymer units resulting from methyl acrylate account for 2 to 30% by weight and copolymer units resulted from acrylic acid account for 1 to 30% by weight, terpolymers of ethylene-methyl acrylate-maleic anhydride, wherein copolymer units resulting from methyl acrylate account for 2 to 30% by weight and copolymer units resulting from maleic anhydride account for 0.2 to 10% by weight, terpolymers of ethylene-butyl acrylate-maleic anhydride, wherein copolymer units resulting from butyl acrylate account for 2 to 30% by weight and copolymer units resulted from maleic anhydride account for 0.2 to 10% by weight, and terpolymers of ethylene-acrylic acid-maleic anhydride, wherein copolymer units resulting from acrylic acid account for 2 to 30% by weight and copolymer units resulting from maleic anhydride account for 0.2 to 10% by weight; copolymers formed by ethylene and glycidyl methacrylate with at least one co-monomer selected from C₁ to C₄ alkyl methacrylate, C₁ to C₄ alkyl acrylate, ethylene-methacrylic acid, ethylene-acrylic acid, and ethylene-maleic anhydride, non-restrictive examples of which include, for example, terpolymers of ethylenebutyl acrylate-glycidyl methacrylate, wherein copolymer units resulting from butyl acrylate account for 2 to 30% by weight and copolymer units resulting from glycidyl methacrylate account for 1 to 15% by weight; and blends of two or more above-described materials.

Preferably, the material employed in layer (b) has a higher MFI at the same temperature than the material employed in layer (a) ad/or (c).

The present invention also relates to a solar panel comprising the following layers a glass layer (a), a first transparent polymer encapsulant layer (b), a layer (c) comprising a photovoltaic cell, a second polymer encapsulant layer (d) comprising a film according to the invention; and a glass layer (e). The invention also relates to a process to manufacture such a solar panel.

Photovoltaic modules derived from wafer-based photovoltaic cells often comprise a series of self-supporting wafers that are soldered together. The wafers generally have a thickness of between about 180 and about 240 μm, commonly known as photovoltaic cell layer. The layer typically further comprises electrical wirings such as cross ribbons connecting the individual cell units and bus bars having one end connected to the cells and the other exiting the module.

The photovoltaic cell layer is usually wedged between layers of polymeric encapsulants and outer protective layers to form a weather resistant module. Possible outer protective layers are glass layers. Subject to the outdoor application, the photovoltaic modules have to be durably resistant to the different weathering conditions, including variations in humidity and temperature, exposure to UV and other radiation, and exposure to chemicals and/or (micro)biological growth related with the outdoor exposure; migration of ions; oxidation, mechanical load though exposure to wind and snow; and resilience against mechanical impacts, such as for instance through hail.

There is a need for an improved solar panel in terms of ease of manufacture and improved solar efficiency. This is achieved by the following solar panel.

A solar panel comprising the following layers:
a glass layer (a),
a first transparent polymer encapsulant layer (b),
a layer (c) comprising a photovoltaic cell,
a second polymer encapsulant layer (d); and
a glass layer (e), wherein the first and/or second polymer encapsulant
is comprised of multiple coextruded thermoplast polymer sub-layers.

The invention is also directed to a process for manufacture of a solar panel. Process to manufacture a solar panel by subjecting a stack comprising the following layers:
a glass layer (a),
a first transparent polymer encapsulant layer (b),
a layer (c) comprising a photovoltaic cell,
a second polymer encapsulant layer (d); and
a glass layer (e), wherein the first and/or second polymer encapsulant
is comprised of multiple coextruded thermoplast polymer sub-layers to
a thermal lamination at an elevated lamination temperature.

Applicants have now surprisingly found that the complexity of a solar panel can be limited by providing an encapsulant layer comprised of multiple coextruded thermoplast polymer sub-layers. This significantly reduces the number of films in the lay-up procedure of the thermal lamination process. Further the amount of waste materials in the manufacturing process is reduced. Further the process to manufacture the solar can be performed requiring no or significantly less solvent based adhesives. Further advantages will be described below.

The role of the glass layer (a) is to protect the photovoltaic module against mechanical impact and weathering while allowing light to pass to the active layer. The role of glass layer (e) is to protect the back side of the solar panel. By having both a front and a back side glass layer an inherently strong panel may be obtained which does not require a frame, such as an aluminium frame. The glass layer may be sodium free glass, for example aluminosilicate or borosilicate glass. For large volume production it is preferred to use a soda lime glass or borosilicate glass. The soda lime glass may comprise between 67-75% by weight Si02, between 10-20% by weight; Na₂O, between 5-15% by weight CaO, between 0-7% by weight MgO, between 0-5% by weight Al₂O₃;between 0-5% by weight K₂O, between 0-1.5% by weight Li₂O and between 0-1%, by weight BaO. Such a glass will suitably have a transparency of higher than 90%. Suitably the glass has been subjected to a thermally toughening treatment.

Preferably the glass layer (a) has a thickness of between 1.5 and 4 mm and wherein the glass layer (e) has a thickness of 1.5 and 4 mm and wherein the total thickness of the solar panel is less than 9 mm.

The glass layer may for example be float glass or roll glass. The glass may optionally be thermally treated. Suitable thermally toughened thin glass sheets glass layers having such a thickness may be obtained from for example Saint Gobain Glass, Pilkington, AGC, PPG and Ducatt.

The surface of the glass layer, especially the surface not facing the polymer sheet is coated with a suitable anti-reflection layer. The anti-reflective layer will limit the radiation which reflects at the glass surface. Limiting this reflection will increase the radiation passing the glass layer (a) which will as a result enhance the efficiency of the solar panel. Preferably a coating is applied to glass layer (a). A suitable anti-reflection coating will comprise of a layer of porous silica. The porous silica may be applied by a sol-gel process as for example described in U.S. Pat. No. 7,767,253. The porous silica may comprise of solid silica particles present in a silica based binder. Such a coating is obtainable from DSM, The Netherlands, as Khepri Coat™. Processes to prepare glass layers having an anti-reflective coating are for example described in WO-A-2004104113 and WO-A-2010100285.

The glass surface of layer (a) facing the incoming radiation may also have an embossed structure to capture incoming radiation more effectively, as for example described in WO2005111670.

The photovoltaic cell may comprise at least one of the following materials: CdS, CdTe; Si, preferably p-doped Si or crystalline Si or amorphous Si or multicrystalline Si; InP; GaAs; Cu2S; Copper Indium Gallium Diselenide (CIGS). Preferably the photovoltaic cell is a monocrystalline silicon (c-Si), poly- or multi-crystalline silicon (poly-Si or mc-Si) and ribbon silicon type photovoltaic cell. The invention is particularly advantageous for these type of cells. Because of the lamination process which shows little shrinkage of the encapsulate layers less forces will be exercised on said PV cells and thus a higher chance of obtaining a good functioning cell results.

The present invention also relates to a process for the preparation of a film according to the invention, comprising the steps of: (i) providing one or more master batch polymer materials for each polymer layer, and (ii) co-extruding the mater batch polymer materials to layers forming the polymer sheet. Preferably, the process further comprises preparing one or more master batches from polymer material and additives, and shaping the master batch material to particulates for use in the coextrusion. The invention also relates to the ue of one or master batches comprising the polymer material and additives for the preparation of a film according to the invention.

The following, non-limiting examples are provided to illustrate the invention.

### EXAMPLE 1

A three layer film comprising two outer layers of EVA, and an intermediate layer of polyethylene was prepared as follows:

A first and a third EVA layer (a) and (c), having a content of 33% VA with an MFI of 45 g/10′ at 190° C. at 2.16 kg were fully formulated with stabilisers and peroxide initiators. These were coextruded at a temperature of about 100° C.; at this temperature the MFI of the individual EVA resin was recorded at ˜2.7 g/10′.

A polyolefine material (b), a low Density polyethylene with an MFI of 22 g/10′ at 190° C. at 2.16 kg, was coextruded in a layer (ii) in between (i) and (iii) at a temperature of ˜120° C. At this temperature the MFI of the individual resin was recorded at ˜3 g/10′.

The layers (a) and (c) were approximately 180 μm thick. Layer (ii) was approximately 90 μm thick. The film when leaving the die was at a temperature of 105° C.

No premature cure of the EVA layers of the film was detected, no melt fracture occurred, and the film was particular thermally stable and showed no shrink sensitivity during the lamination process.

EVA layer (c) was pigmented with a diffuse reflector of type TiO₂. The presence of the pigments was found to not influence the ease of processing the film where the melt temperature of both resins is substantially different, EVA melting at about 63° C., whereas LDPE melts at about 105° C.

The co-extrusion was realized on a conventional feed-block and die hardware, without the use of a multi-manifold die.

The thus prepared multilayer film (d) was employed in a lay-up of a solar panel, whereby a stack of a glass layer, a first transparent traditional EVA monolayer encapsulant film, a crystalline silicon PV cell, the above obtained multi-layer film (d) and a glass layer as back sheet were subjected to a thermal lamination process at a lamination temperature of about 150° C., using the following lamination protocol on a flat-bed vacuum laminator from Meier (settings):

Temperature: 145° C.

Vacuum time: 300 seconds

Pressure ramp up: 30 seconds

Press time: 400 seconds The thus obtained cells showed no flow of a white pigmented layer into the front of the PV cells, and passed accelerated humidity and heat exposure tests. The thus obtained multilayer (d) did not show significant shrinkage upon cooling and/or during the above described lamination.

### EXAMPLE 2

Example 1 was repeated, however using film that had been cut off from the first film before lamination, and then subjected to an extrusion and pelletization prior to the co-extrusion, as layer (b). The thus obtained film was employed for a cell according to example 1, and performed similar to the original film.

### Comparative Example 1

Example 1 was repeated, however using a monolayer, white pigmented EVA encapsulant at the backside. When laminating, a substantial amount of white EVA was found to blend with the transparent front EVA encapsulant, hence migrating onto the front of the photovoltaic cells, while also a small part of the transparent front EVA was found to flow to the back of the module, leaving transparent stains in the module. Next to the undesired aesthetical effect, the partial covering of the cells leads to a decreased output thereby reducing the effectiveness to convert incandescent light.

Variation of the lamination cycle, such as varied vacuum time, maximum pressure and temperature, did not affect the quality of the samples, whereas the overflow in comparative example remained present in any case.

The examples above clearly shows the advantages of the process and materials of the present invention, in particular the reduction of waste material through re-use, but also the reduction of overflow of a pigmented layer onto the front of the photovoltaic element.

This makes the films according to the invention specifically suited for the used with e.g. back-contact cells.

Although several specific embodiments of the present invention have been described in the detailed description above, this description is not intended to limit the invention to the particular form or embodiments disclosed herein since they are to be recognised as illustrative rather than restrictive, and it will be obvious to those skilled in the art that the invention is not limited to the examples.

1. A multilayer film for the encapsulation of photovoltaic cells, comprising:
(a) at least a first, outer thermoplastic polymer layer;
(b) a thermoplastic polymer intermediate layer arranged between the first and a second outer layer, and
(c) a second outer thermoplastic polymer layer,
wherein (a) is transparent, while at least one of (b) or (c) is opaque, wherein at least one of layers (a) to (c) comprises an ethylene vinyl acetate co-polymer, and wherein the content ratio of a constituent unit derived from vinyl acetate in the ethylene vinyl acetate copolymer employed in layers (a) to (c) is 18% by mass or more and wherein the one or more opaque layer(s) comprises diffuse reflective pigments, and has a reflective efficiency of at least 75% for light with a wavelength in the range of from 400 to 800 nm, as determined according to ASTM standard E 903, at an opaque layer thickness of from 30 to 500 μm; and
wherein the multilayer film is employed on the backside of a photovoltaic cell.

2-48. (canceled)

49. The film according to claim 1, wherein the one or more opaque layer(s) comprises diffuse reflective pigments, and has a reflective efficiency of at least 95% for light with a wavelength In the range of from 400 to 800 nm, at an opaque layer thickness of 50 to 250 μm.

50. The film of claim 1, wherein an outer polymer layer has a melting point T1 which at least 10° C. below the melting point T2 of at least one of the remaining polymer layers, preferably wherein the melting point T1 is between 10 and 100° C. lower than the melting point T2.

51. The film of claim 1, wherein intermediate layer (b) comprises an optionally functionalized polyolefin, an optionally functionalized polyolefine co- or terpolymer; an optionally hydrogenated polystyrene block copolymer with butadlene, isoprene and/or butyleneslethylene copolymers (SIS, SBS and/or SEBS); a polymethacrylate polyacrylate block copolymer, a polyolefin, or an olefin copolymer with copolymerizable functionalised monomers such as methacyryllc acid (ionomer).

52. The film according to claim 50, wherein the melt flow index of layer (b) at the extrusion temperature Tb of layer (b) is equal to or in the range of from −2 to plus 2 MFI to the MFI of layers (a) and/or (c) at the extrusion temperature Ta or To of layers (a) and/or (c).

53. The film according to claim 52, wherein the MFI of layer (b) differs in a range of from 0.5 to 10 from the MFI of layer (a) and/or (c) at a temperature TL, wherein TL is the lamination temperature of a vacuum lamination for photovoltaic modules comprising the film, and wherein T2 is equal to, higher or lower than Tb, and wherein Tb Is higher than Ta and preferably, wherein the MFI of the layers (a) and/or (c) is higher than the MFI of layer (b) at TL.

54. The film according to claim 1, wherein layers (a) or (c) comprise a silane adhesion promoter in an amount sufficient to achieve adhesion with silicon, metal and/or metal oxide derived surfaces, such as glass and/or photovoltaic cells.

55. The film according to claim 1, wherein layers (a), (b) and/or (c) further comprise one or more crosslinking system activated at the lamination temperature TL, preferably wherein the crosslinking system comprises organic peroxide initiators.

56. The film according to claim 1, wherein layers (a), (b) and (c) are adhered to each other by a coextrusion process.

57. The film according to claim 1, wherein layer (a) comprises virgin material, and wherein layer (b) and/or (c) comprises at least in part recycled material.

58. The film according to claim 57, wherein layer (b) and/or (c) comprises at least in part of ethylene vinyl acetate material that was removed by trimming from the film, and subsequently resized.

59. The film according to claim 1, wherein the layer (b) and/or (c) comprise less silane than layer (a).

60. A process for the manufacture of a film according to claim 1, comprising the steps of:
(i) providing at least a first thermoplastic polymer material suitable as encapsulant material;
(ii) providing at least a second thermoplastic polymer material suitable as encapsulant material;
(iii) providing at least a third thermoplastic polymer material suitable as intermediate polymer material, and
(iv) coextruding a film comprising at least three layers of the respective encapsulant materials (i) to (iii); and preferably, wherein materials (i) and (ii) comprise an ethylene vinyl acetate co-polymer.

61. A process for the preparation of a photovoltaic module, comprising adhering the film according to claim 1 to the front and/or the backside of a photovoltaic cell layer, and heating the combined layers to lamination temperature TL above the melting point of layers (a) and (c), and optionally above the melting point of layer (b).

62. The process according to claim 60, further comprising trimming the coextruded film obtained to a desired width and/or length, and subjecting the trimmed off film material to resizing to obtain a recycled trim material.

63. A photovoltaic module comprising the multilayer film of claim 1.

64. A multilayer backsheet film for the production of photovoltaic cells, comprising:
(a) a first transparent upward facing outer encapsulant layer;
(b) a second encapsulant layer adjacent to the first layer;
(c) an optional further downward facing encapsulant layer; and
(d) a polymer film,
wherein at least one of layers (b) or (c) is opaque and wherein layer (b) and/or (c) comprises diffuse reflective pigments, and wherein layer (b) and/or (c) has a reflection efficiency of at least 75% for light with a wavelength In the range of from 400 to 800 nm, as determined according to ASTM standard E 903; wherein one or more layers (a), (b) and/or (c) comprise an ethylene vinyl acetate co-polymer, wherein the content ratio of a constituent unit derived from vinyl acetate in the ethylene vinyl acetate co-polymer employed in layers (a), (b) and/or is 18% by mass or more.

65. The backsheet film according to claim 64, wherein the polymer film (d) comprises a bioriented partly aromatic polyester and an adhesion promoting layer enhancing the adhesion of the polyester film to the encapsulant layers (b) or (c), and preferably further comprising a protective layer (e) comprising a fluoropolymer, wherein (e) is directly attached to layer (d) at the side distal to layer (c).

66. The backsheet film according to claim 64, wherein layer (b) and/or (c) comprise diffuse reflective pigments, wherein the pigments comprise preferably coated inert titanium oxide and/or mica.

67. The backsheet film of claim 64, wherein layer (b) comprises an ethylene vinyl acetate co-polymer different from the ethylene vinyl acetate co-polymer employed in (a); a block copolymer such as hydrogenated polystyrene block copolymer with butadiene, isoprene and/or butylenes/ethylene eopolymers (SIS, SBS and/or SEBS); a polymethacrylate polyacrylate block copolymer, a polyolefin, or an olefin copolymar with copolymerizable functionalised monomers such as methaoyrylic acid (ionomer);
an optionally functlonalized polyolefin, a polyuretnane, and/or a silicone polymer.

68. A photovoltaic module comprising a laminated backsheet film according to claim 64, preferably further comprising a front sheet and a front encapsulant comprising an ethylene vinyl acetate co-polymer encapsulant layer, and a photovoltaic cell embedded in the front encapsulant layer and layer (a), more preferably wherein the front sheet comprises one or more glass plates having a thickness of from 1.6 to 4 mm.

69. A process for the preparation of a film according to claim 1, comprising the steps of: (i) providing one or more master batch polymer materials for each polymer layer, and (ii) co-extruding the mater batch polymer materials to layers forming the polymer sheet, preferably further comprising preparing one or more master batches from polymer material and additives, and shaping the master batch material to particulates for use in the coextrusion.
